(19) United States
(12) Patent Application Publication
(10) Pub. No.: US 2020/0315037 A1
(43) Pub. Date: Oct. 1, 2020

(54) ELECTRONIC DEVICE PROVIDED WITH SPECIAL-SHAPED DISPLAY SCREEN

(71) Applicant: JRD COMMUNICATION (SHENZHEN) LTD., SHENZHEN (CN)

(72) Inventors: GUOPING JIAN, SHENZHEN (CN); WENLIANG LU, SHENZHEN (CN)

(21) Appl. No.: 16/759,314

(22) PCT Filed: Oct. 25, 2018
(86) PCT No.: PCT/CN2018/111886

§ 371 Date: Apr. 24, 2020

(30) Foreign Application Priority Data
Oct. 25, 2017 (CN) 201711006818.4

(51) Int. Cl. H05K 5/00; H05K 5/02; H04L 12/28

(52) U.S. Cl. CPC H05K 5/0017; H04L 12/2898; H05K 5/0086; H05K 5/0217

(57) ABSTRACT

Provided is an electronic device provided with a special-shaped display screen. The device comprises: a front shell, wherein the front shell is provided with a through hole; a rear shell, which is arranged opposite the front shell, wherein an accommodating space is formed between the rear shell and the front shell; a bracket, which is arranged in the accommodating space, wherein the bracket is located on the rear shell a rectangular display screen, which is located on the surface, facing the front shell, of the bracket, wherein the rectangular display screen comprises a display portion, and the display portion is aligned with the through hole; and a transparent sheet, which is fixed in the through hole.

### TECHNICAL FIELD

The present disclosure relates to the field of display technologies, and in particular, to an electronic device with a special-shaped display screen.

### BACKGROUND

With continuous development of display screen technologies, display screens are no longer limited to traditional rectangular shapes. At present, non-rectangular display screens, such as circular display screens, have already appeared. Moreover, currently popular smart wearable products or other electronic devices have also gradually introduced designs of round screens for consideration of various aspects, such as aesthetics, ergonomics, and so on. Rounded screens meet diversified consuming requirements of consumers and have a large market prospect.

However, at present, related technologies of circular display screens are still immature, for example, space of circular display screens is insufficient, and a backlight is too close to a light-shielding foam, which results in that light leakage is prone to exist during display. As a result, cost of circular display screens remains high. Compared with mature technologies of rectangular display screens, existing circular display screens have no advantage in whether technology or cost.

### SUMMARY

The present disclosure provides an electronic device with a special-shaped display screen, comprising:

a front shell provided with a through hole;

a rear shell arranged to be opposite to the front shell, wherein an end of the rear shell is fixedly connected with an end of the front shell, so that accommodating space is formed between the rear shell and the front shell;

a bracket arranged in the accommodating space, wherein the bracket is located on the rear shell, and a middle portion of a surface of the bracket facing the rear shell recesses to form a groove;

a rectangular display screen located on a surface of the bracket facing the front shell, wherein the rectangular display screen comprises a display portion and a non-display portion, the display portion is aligned with the through hole, a projection of the through hole on the display portion is located in the display portion, the non-display portion surrounds the display portion, and the non-display portion is connected with the display portion;

a battery arranged in the groove of the bracket and configured to provide power supply for the electronic device; and

a transparent sheet fixed in the through hole, wherein the transparent sheet includes a light transmitting portion and a light shielding portion, the light transmitting portion is aligned with the display portion, and the light shielding portion is aligned with the non-display portion;

wherein; a shape of the display portion; a shape of a section of the through hole, and a shape of the transparent sheet are the same.

Wherein, the shape of the transparent sheet is any one of circle; triangle; diamond; and ellipse.

Wherein, an inner wall of the through hole extends inwards to form a bearing platform, the bearing platform is arranged on the non-display portion, and the light shielding portion is fixed on the bearing plat.

Wherein, the electronic device further comprises a dustproof foam, the dustproof foam is arranged between the bearing platform and the non-display portion.

Wherein, a double sided tape is arranged between the dustproof foam and the bearing platform and/or between the dustproof foam and the non-display portion.

Wherein, the electronic device further comprises a portable wireless router.

Wherein, in the rectangular display screen, a state of the non-display portion is set to be a non-display state or displaying black.

Wherein, a protection layer is formed by printing using a screen printing manner on a surface of the light shielding portion away from the rectangular display screen.

The present disclosure provides another electronic device with a special-shaped display screen, comprising:

a front shell provided with a through hole;

a rear shell arranged to be opposite to the front shell, wherein an end of the rear shell is fixedly connected with an end of the front shell, so that accommodating space is formed between the rear shell and the front shell;

a bracket arranged in the accommodating space, wherein the bracket is located on the rear shell;

a rectangular display screen located on a surface of the bracket facing the front shell, wherein the rectangular display screen comprises a display portion; the display portion is aligned with the through hole; and a projection of the through hole on the display portion is located in the display portion; and

a transparent sheet fixed in the through hole.

Wherein, a shape of a section of the through hole and a shape of the transparent sheet are the same.

Wherein, the shape of the transparent sheet is any one of circle; triangle; diamond; and ellipse.

Wherein, the rectangular display screen further comprises a non-display portion, the non-display portion surrounds the display portion, and the non-display portion is connected with the display portion;

the transparent sheet includes a light transmitting portion and a light shielding portion, the light transmitting portion is aligned with the display portion, and the light shielding portion is aligned with the non-display portion.

Wherein, an inner wall of the through hole extends inwards to form a bearing platform, the bearing platform is arranged on the non-display portion, and the light shielding portion is fixed on the bearing plat.

Wherein, the electronic device further comprises a dustproof foam, the dustproof foam is arranged between the bearing platform and the non-display portion.

Wherein, a double sided tape is arranged between the dustproof foam and the bearing platform and/or between the dustproof foam and the non-display portion.

Wherein, the electronic device further comprises a portable wireless router.

Wherein, in the rectangular display screen, a state of the non-display portion is set to be a non-display state or displaying black.

Wherein, a protection layer is formed by printing using a screen printing manner on a surface of the light shielding portion away from the rectangular display screen.

### BRIEF DESCRIPTION OF THE DRAWINGS

The above and other aspects, characteristics, and advantages of embodiments of the present disclosure will become clearer through the following description in accompany with the drawings.

FIG. 1 is a disassembled structural schematic view of an electronic device with a special-shaped display screen according to an embodiment of the present disclosure.

FIG. 2 is a structural schematic view of an electronic device with a special-shaped display screen according to an embodiment of the present disclosure.

FIG. 3 is a cross-section view along the direction A-A in FIG. 2.

FIG. 4 is an enlarged view of the part B in FIG. 3.

### DETAILED DESCRIPTION

Embodiments of the present disclosure will be described in detail with reference to the drawings below. However, the present disclosure can be implemented in many different manners, and the present disclosure should not be interpreted as being limited to the specific embodiments described herein. On the contrary, these embodiments are provided in order to illustrate principle and actual application of the present disclosure, so that other ones skilled in the art in this field can understand various embodiments and various modifications adapted to specific desired application of the present disclosure.

In the drawings, shapes and sizes of elements can be exaggerated for clarity, and identical reference numbers will be always used to represent identical or similar elements.

It will be understood that although terms “first”, “second” and the like can be used herein to describe various elements, these elements should not be limited by these terms. These terms are only used to distinguish one element from another element.

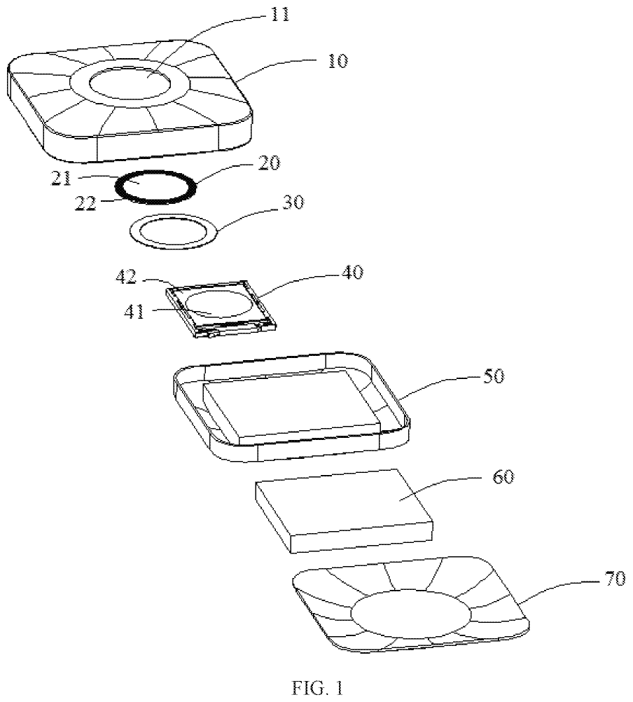

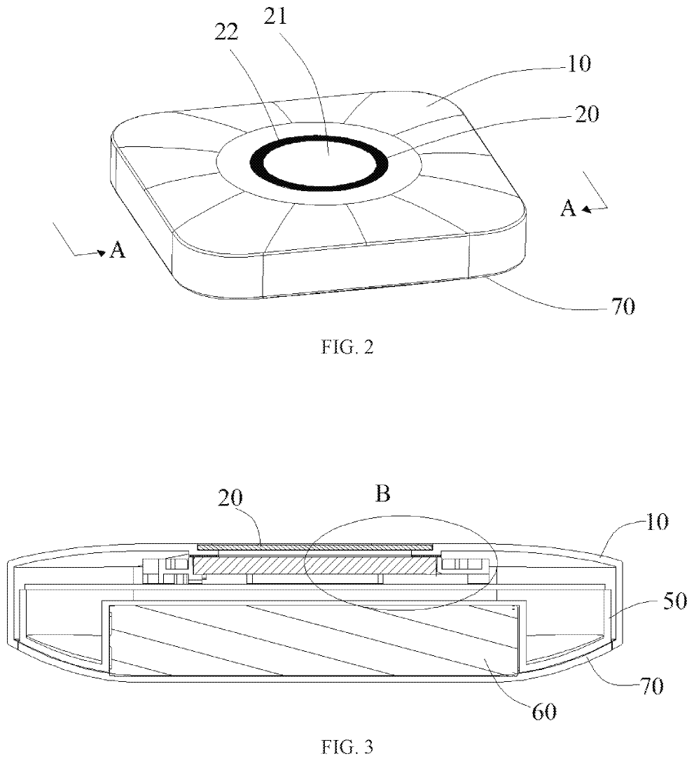

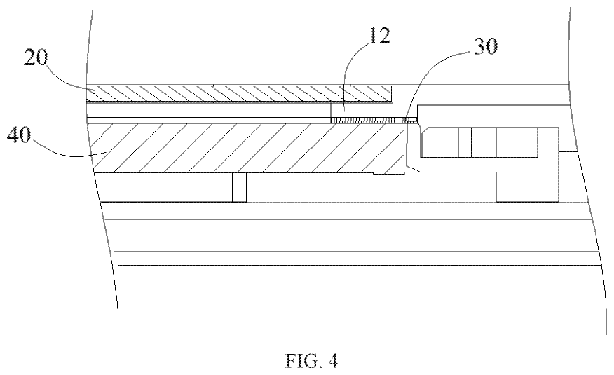

FIG. 1 is a disassembled structural schematic view of an electronic device with a special-shaped display screen according to an embodiment of the present disclosure. FIG. 2 is a structural schematic view of an electronic device with a special-shaped display screen according to an embodiment of the present disclosure. FIG. 3 is a cross-section view along the direction A-A in FIG. 2. FIG. 4 is an enlarged view of the part B in FIG. 3.

Referring to FIG. 1, FIG. 2, FIG. 3, and FIG. 4, an electronic device with a special-shaped display screen according to an embodiment of the present disclosure comprises: a front shell 10, a transparent sheet 20, a dustproof foam 30, a rectangular display screen 40, a bracket 50, a battery 60, and a rear shell 70. It should be noted that the present disclosure is not limited herein, and the electronic device with a special-shaped display screen of the present disclosure can further comprise other necessary elements.

In particular, the front shell 10 is provided with a through hole 11. As one embodiment of the present disclosure, an inner wall of the through hole 11 extends inwards to form a bearing platform 12. The through hole 11 is configured to place the transparent sheet 20, in particular, the bearing platform 12 in the through hole 11 is configured to bear the transparent sheet 20.

The rear shell 70 is arranged to be opposite to the front shell 10, an end of the rear shell 70 is fixedly connected with an end of the front shell 10, so that accommodating space is formed between the rear shell 70 and the front shell 10.

The bracket 50 is arranged in the accommodating space, and the bracket 50 is located on the rear shell 70. The bracket 50 is configured to bear the rectangular display screen 40. A middle portion of a surface of the bracket 50 facing the rear shell 70 recesses to form a groove.

The battery 60 is arranged in the groove of the bracket 50 to provide power supply for the electronic device.

The rectangular display screen 40 is located on a surface of the bracket 50 facing the front shell 10. The rectangular display screen 40 comprises a display portion 41 and a non-display portion 42, wherein, the display portion 41 is aligned with the through hole 11, the non-display portion 42 surrounds the display portion 41, and the non-display portion 42 is connected with the display portion 41. The display portion 41 is a working area of the rectangular display screen 40, which is used to display interfaces and interact with users. The non-display portion 42 is a non-working area, and a state of the non-display portion 42 can be set to be a non-display state or displaying black. By a software system, a shape and a position of the display portion 41 of the rectangular display screen 40 can be set, such that the rectangular display screen 40 only displays a display interface of a special shape. In particular, the display portion 41 is aligned with the through hole 11, a shape of the through hole 11 matches with the display portion 41, and a projection of the through hole 11 on the display portion 41 is located in the display portion 41.

The transparent sheet 20 is fixed in the through hole 11. In particular, the transparent sheet is fixed on the bearing platform 12. According to an embodiment of the present disclosure, the transparent sheet 20 includes a light transmitting portion 21 and a light shielding portion 22. The light transmitting portion 21 is aligned with the display portion 41, a user can see content appearing on the display portion 41 through the light transmitting portion 21. The light shielding portion 22 is aligned with the non-display portion 42, a protection layer is printed using a screen printing manner on a surface of the light shielding portion 22 away from the rectangular display, screen 40, so as to provide a light shielding action.

The dustproof foam 30 is arranged between the bearing platform and the non-displaying portion 42. As an embodiment of the present disclosure, a double sided tape (not shown in the drawings) is arranged between the dustproof foam 30 and the bearing platform 12 and/or between the dustproof foam 30 and the non-display portion 42, and is configured to fix the dustproof foam 30 on the bearing platform 12 and/or the non-display portion 42. It can be understood that the present disclosure is not limited herein, and it is also possible to adopt other suitable methods to fix the dustproof foam 30 on the bearing platform 12 and/or the non-display portion 42. The dustproof foam 30 not only can prevent dust from entering the display portion 41, but also prevent light leakage at edges of the rectangular display screen 40 from entering the display portion 41.

In particular, a shape of the display portion 41, a shape of a section of the through hole 11, and a shape of the transparent sheet 20 are the same. In the drawings of the embodiment of the present disclosure, the shape of the transparent sheet 20 is set to be circle. However, the present disclosure is not limited herein, the shape of the transparent sheet 20 can be set according to demands of users and design requirements of products, for example, triangle, diamond, ellipse, and so on. Since technologies of special-shaped display screens are immature, there exist situations of high cost and instable display in actual use. However, rectangular display screens are the most commonly used display screens at present, rectangular display screens are more mature in technology and lower in price. In addition, by setting in a software system, a shape and a position of a user interface of a rectangular display screen can be controlled. Thus, by matching a through hole and a transparent sheet which have corresponding shapes, effect of a display screen with a corresponding shape can be present.

It should be noted that an electronic device according to an embodiment of the present disclosure can be a portable wireless router.

In the present disclosure, by setting a size and a shape of a display portion of a rectangular display screen, setting a non-display portion to be in a non-display state or display black, and then setting a through hole and a transparent sheet aligned with and having the same shape as the display portion, the rectangular display sheet is enabled to appear display effect of a special-shaped screen, such as a circular screen, which not only meets diversified requirements of consumers, but also is based on more mature rectangular display screen technologies, display effect is more stable, and cost is low.

Although the present disclosure has already been shown and described with reference to certain embodiments, those skilled in the art should understand that various changes in forms and details can be made herein without departing from the spirit and scope of the present disclosure defined by the claims and their equivalents.

1. An electronic device with a special-shaped display screen, comprising:
a front shell provided with a through hole;
a rear shell arranged to be opposite to the front shell, wherein an end of the rear shell is fixedly connected with an end of the front shell, so that accommodating space is formed between the rear shell and the front shell;
a bracket arranged in the accommodating space, wherein the bracket is located on the rear shell, and a middle portion of a surface of the bracket facing the rear shell recesses to form a groove;
a rectangular display screen located on a surface of the bracket facing the front shell, wherein the rectangular display screen comprises a display portion and a non-display portion, the display portion is aligned with the through hole, a projection of the through hole on the display portion is located in the display portion, the non-display portion surrounds the display portion, and the non-display portion is connected with the display portion;
a battery arranged in the groove of the bracket and configured to provide power supply for the electronic device; and
a transparent sheet fixed in the through hole, wherein the transparent sheet includes a light transmitting portion and a light shielding portion, the light transmitting portion is aligned with the display portion, and the light shielding portion is aligned with the non-display portion;
wherein, a shape of the display portion, a shape of a section of the through hole, and a shape of the transparent sheet are the same.

2. The electronic device according to claim 1, wherein, the shape of the transparent sheet is any one of circle, triangle, diamond, and ellipse.

3. The electronic device according to claim 1; wherein, an inner wall of the through hole extends inwards to form a bearing platform, the bearing platform is arranged on the non-display portion, and the light shielding portion is fixed on the bearing plat.

4. The electronic device according to claim 1, wherein; the electronic device further comprises a dustproof foam, the dustproof foam is arranged between the bearing platform and the non-display portion.

5. The electronic device according to claim 4, wherein, a double sided tape is arranged between the dustproof foam and the bearing platform and/or between the dustproof foam and the non-display portion.

6. The electronic device according to claim 1, wherein, the electronic device further comprises a portable wireless router.

7. The electronic device according to claim 1, wherein, in the rectangular display screen; a state of the non-display portion is set to be a non-display state or displaying black.

8. The electronic device according to claim 1, wherein, a protection layer is formed by printing using a screen printing manner on a surface of the light shielding portion away from the rectangular display screen.

9. An electronic device with a special-shaped display screen, comprising:
a front shell provided with a through hole;
a rear shell arranged to be opposite to the front shell, wherein an end of the rear shell is fixedly connected with an end of the front shell, so that accommodating space is formed between the rear shell and the front shell;
a bracket arranged in the accommodating space, wherein the bracket is located on the rear shell,
a rectangular display screen located on a surface of the bracket facing the front shell; wherein the rectangular display screen comprises a display portion, the display portion is aligned with the through hole, and a projection of the through hole on the display portion is located in the display portion; and
a transparent sheet fixed in the through hole.

10. The electronic device according to claim 9, wherein, a shape of a section of the through hole and a shape of the transparent sheet are the same.

11. The electronic device according to claim 10, wherein; the shape of the transparent sheet is any one of circle, triangle, diamond, and ellipse.

12. The electronic device according to claim 9, wherein, the rectangular display screen further comprises a non-display portion, the non-display portion surrounds the display portion, and the non-display portion is connected with the display portion;
the transparent sheet includes a light transmitting portion and a light shielding portion, the light transmitting portion is aligned with the display portion, and the light shielding portion is aligned with the non-display portion.

13. The electronic device according to claim 12, wherein, an inner wall of the through hole extends inwards to form a bearing platform, the bearing platform is arranged on the non-display portion, and the light shielding portion is fixed on the bearing plat.

14. The electronic device according to claim 13, wherein; the electronic device further comprises a dustproof foam, the dustproof foam is arranged between the bearing platform and the non-display portion.

15. The electronic device according to claim 14, wherein, a double sided tape is arranged between the dustproof foam and the bearing platform and/or between the dustproof foam and the non-display portion.

16. The electronic device according to claim 9, wherein, the electronic device further comprises a portable wireless router.

17. The electronic device according to claim 9, wherein, in the rectangular display screen; a state of the non-display portion is set to be a non-display state or displaying black.

18. The electronic device according to claim 9, wherein, a protection layer is formed by printing using a screen printing manner on a surface of the light shielding portion away from the rectangular display screen.

19. An electronic device, comprising:
a front shell provided with a through hole;
a light transmission sheet fixed in the through hole and comprising a light transmitting portion;
a rear shell cooperating with the front shell to form accommodating space between the rear shell and the front shell;
a bracket arranged in the accommodating space;
a rectangular display screen located on the bracket facing the front shell and comprising a display portion aligned with the through hole;
wherein, a shape of the display portion, a shape of the light transmitting portion, and a shape of a section of the through hole are all the same preset special shape, so that display effect of a special-shaped screen of the preset special shape appears in the through hole.

20. The electronic device according to claim 19, wherein, the preset special shape any one of circle, triangle, diamond, and ellipse.
